(19) United States
(12) Patent Application Publication
(10) Pub. No.: US 2010/0019776 A1
(43) Pub. Date: Jan. 28, 2010

(54) METHOD FOR ANALYZING SUPERCONDUCTING WIRE

(76) Inventors: Douglas C. Folts, Baraboo, WI (US); Eric R. Podtburg, Natick, MA (US); Robert C. Diehl, Holden, MA (US)

Correspondence Address: Holland & Knight LLP, 10 St. James Ave., Boston, MA, 02116, US

(21) Appl. No.: 12/178,456

(22) Filed: Jul. 23, 2008

(51) Int. Cl. G01R 31/02; H01B 12/02

(52) U.S. Cl. 324/539; 505/230; 174/125.1

(57) ABSTRACT

The present disclosure relates to a system and method for analyzing a superconducting wire. A method in accordance with at least one embodiment described herein may include performing a voltage/current (VI) test for each of a plurality of portions of superconducting wire. The VI test may include determining a plurality of VI data points for each of the plurality of portions of superconducting wire at a first VI datapoint of about (Ic (critical current), Ec (critical electric field)) and at a second VI datapoint of about (Ix, Ex). Ex may be at least 10 times Ec and Ix may be approximately equal to the current resulting at that voltage drop. The method may further include analyzing the plurality of VI data points for each portion of superconducting wire to determine if one or more of the portions of superconducting wire are defective. Of course, numerous other embodiments are also within the scope of the present disclosure.

### GOVERNMENT RIGHTS

This invention was made with Government support under Agreement No.: HSHQDC-08-9-00001. The Government has certain rights in the invention.

### TECHNICAL FIELD

This disclosure relates to high temperature superconducting (HTS) devices and, more particularly, to a method for testing HTS devices configured to operate as fault current limiting devices.

### BACKGROUND

As worldwide electric power demands continue to increase significantly, utilities have struggled to meet these increasing demands both from a power generation standpoint as well as from a power delivery standpoint. Delivery of power to users via transmission and distribution networks remains a significant challenge to utilities due to the limited capacity of the existing installed transmission and distribution infrastructure, as well as the limited space available to add additional conventional transmission and distribution lines and cables. This is particularly pertinent in congested urban and metropolitan areas, where there is very limited existing space available to expand capacity.

Flexible, long-length power cables using HTS wire are being developed to increase the power capacity in utility power transmission and distribution networks, while maintaining a relatively small footprint for easier installation and using environmentally clean liquid nitrogen for cooling. For this disclosure, an HTS material is defined as a superconductor with a critical temperature at or above 30° Kelvin (minus 243° Centigrade), which includes materials such as rare-earth or yttrium-barium-copper-oxide (herein called YBCO); thallium-barium-calcium-copper-oxide; bismuth-strontium-calcium-copper-oxide (herein called BSCCO); mercury-barium-calcium-copper-oxide; and magnesium diboride. These composition families are understood to include possible substitutions, additions and impurities, as long as these substitutions, additions and impurities do not reduce the critical temperature below 30° K. Such HTS cables allow for increased amounts of power to be economically and reliably provided within congested areas of a utility power network, thus relieving congestion and allowing utilities to address their problems of transmission and distribution capacity.

An HTS power cable uses HTS wire as the primary conductor of the cable (i.e., instead of traditional copper conductors) for the transmission and distribution of electricity. The design of HTS cables results in significantly lower series impedance, in their superconducting operating state, when compared to conventional overhead lines and underground cables. Here, the series impedance of a cable or line refers to the combination of the resistive impedance of the conductors carrying the power, and the reactive (inductive) impedance associated with the cable architecture or overhead line. For the same cross-sectional area of the cable, HTS wire enables a three to five times increase in current-carrying capacity when compared to conventional alternating current (AC) cables; and up to a ten times increase in current-carrying capacity when compared to conventional direct current (DC) cables.

HTS cables may be designed with HTS wires helically wound around a continuously flexible corrugated former, or they may have multiple HTS wires in a variety of stacked and twisted configurations. In all these cases the cable may be continuously flexible, so that it can be wound conveniently on a drum for transportation and installed with bends and turns in a conduit or between other power devices. HTS cables may be designed with a liquid cryogen in contact with the HTS wires and flowing along the length of the cable. Liquid nitrogen is the most common liquid cryogen, but liquid hydrogen or liquid neon could be used for lower temperature superconducting materials like magnesium diboride.

In addition to capacity problems, another significant problem for utilities resulting from increasing power demand (and hence increased levels of power being generated and transferred through the transmission and distribution networks) are increased “fault currents” resulting from “faults”. Faults may result from network device failures, acts of nature (e.g. lightning), acts of man (e.g. an auto accident breaking a power pole), or any other network problem causing a short circuit to ground or from one phase of the utility network to another phase. In general, such a fault appears as an extremely large load materializing instantly on the utility network. In response to the appearance of this load, the network attempts to deliver a large amount of current to the load (i.e., the fault). Any given link in the network of a power grid may be characterized by a maximum fault current which will flow, in the absence of fault current limiting measures, during the short circuit that precipitates the maximum fault condition. The fault currents may be so large in large power grids that without fault current limiting measures, most electrical equipment in the grid may be damaged or destroyed. The conventional way of protecting against fault currents is to rapidly open circuit breakers and completely stop the current and power flow.

Detector circuits associated with circuit breakers may monitor the network to detect the presence of a fault (or over-current) situation. Within a few milliseconds of detection, activation signals from the detector circuits may initiate the opening of circuit breakers to prevent destruction of various network components. Currently, the maximum capability of existing circuit breaker devices is 80,000 amps, and these are for transmission level voltages only. Many sections of the utility network built over the previous century were built with network devices capable of withstanding only 40,000 to 63,000 amps of fault current. Unfortunately, with increased levels of power generation and transmission on utility networks, fault current levels are increasing to the point where they will exceed the capabilities of presently installed or state-of-the-art circuit breaker devices (i.e., be greater than 80,000 amps) both at distribution and transmission level voltages. Even at lower fault current levels, the costs of upgrading circuit breakers from one level to a higher one across an entire grid can be very high. Accordingly, utilities are looking for new solutions to deal with the increasing level of fault currents. In most cases, it is desirable to reduce fault currents by at least 10% to make a meaningful improvement in the operation of a grid. One such solution in development is a device called an HTS fault current limiter (FCL).

An HTS FCL is a dedicated device interconnected to a utility network that reduces the amplitude of the fault currents to levels that conventional, readily available or already installed circuit breakers may handle. See High-Temperature Superconductor Fault Current Limiters by Noe and M. Steurer, Supercond. Sci. Technol. 20 (2007) R15-R 29. Such HTS FCLs have typically been configured out of short rigid modules made of solid bars or cylinders of HTS material which have very high resistance when they are driven over their superconducting critical current into a resistive state. Unfortunately, such standalone HTS FCLs are currently quite large and expensive. Space is particularly at a premium in substations in dense urban environments where HTS cables are most needed. Utilities may also use large inductors, but they may cause extra losses, voltage regulation and grid stability problems. And, unfortunately, pyrotechnic current limiters (e.g., fuses) need replacement after every fault event. Further, while new power electronic FCLs are under development, there are questions about whether they can be fail-safe and whether they can be extended reliably to transmission voltage levels.

To allow HTS cables to survive the flow of fault currents, a significant amount of copper is introduced in conjunction with the HTS wire, but this adds to the weight and size of the cable. See Development and Demonstration of a Long Length HTS Cable to Operate in the Long Island Power Authority Transmission Grid by J. F. Maguire, F. Schmidt, S. Bratt, T. E. Welsh, J. Yuan, A. Allais, and F. Hamber, to be published in IEEE Transaction on Applied Superconductivity. Often, copper fills the central former in the core of the HTS cable around which the HTS wire is helically wound, which prevents the core from being used as a passage for the flow of liquid nitrogen. Alternatively, especially for multi-phase cables, copper wires are mixed in with the HTS wires within the helically wound layers of the cable. In the presence of a large fault current that exceeds the critical current of the HTS wires of the cable, they quench or switch to a resistive state that can heat from resistive I²R losses (where I is the current and R is the resistance of the cable). The copper is designed to absorb and carry the fault current to prevent the HTS wires from over-heating. The amount of copper is so large that its total resistance in the cable is small and, therefore, has a negligible effect in reducing the fault current.

An HTS wire may require a significant amount of testing to verify the proper operation of the wire. Specifically, in the past, the most basic requirement has been that the wire being tested have a critical current (Ic) of above some minimum value. For example, in the case of a non-fault current limiting wire, the specification may require a minimum Ic of 135 A. In contrast, a fault current limiting wire may require a maximum Ic specification, in addition to the minimum Ic specification, in order to ensure that the current limiting aspect functions properly.

During operation, HTS wires may exhibit variations in Ic along the length of the wire. The Ic is typically measured on a one meter length of wire and may be defined as the current which produces a 1 μV/cm electric field in the wire when the wire is at 77.3K (i.e., boiling liquid nitrogen (LN2) temperature at 1 atmosphere absolute temperature) with no external magnetic field. Random Ic variations (RIVS) of ±10% around the medium Ic value is fairly common. However, over a short length of wire (e.g., 4 cm) larger variations above a certain threshold may be present. These variations are referred to as pop-ups if the Ic spikes in an upwards direction. Alternatively, large variations below a certain threshold are referred to as drop-outs if the Ic spikes downwards.

In the past, the drop-out sections of wire have been deemed defective requiring the removal of a portion of the wire. The remaining “acceptable” wire was then spliced together to make a continuous wire. However, identifying defective portions of wire with precision has been difficult. As a result, excessive amounts of acceptable wire have been discarded along with the defective wire.

Thus, it is desirable to improve the method by which HTS wires are tested. Specifically, a method for more accurately identifying the acceptable and unacceptable portions of a HTS wire would improve efficiency during manufacturing and testing, decrease costs and maximize wire production yield.

### SUMMARY OF DISCLOSURE

In a first implementation of this disclosure, a test method for analyzing a superconducting wire is provided. The method may include performing a voltage/current (VI) test for each of a plurality of portions of superconducting wire. The VI test may include determining a plurality of VI data points for each of the plurality of portions of superconducting wire at a first VI datapoint of about (Ic (critical current), Ec (critical electric field)) and at a second VI datapoint of about (Ix, Ex). Ex may be approximately equal to at least 10 times Ec and Ix may be approximately equal to the current resulting at that voltage drop. The method may further include analyzing said plurality of VI data points for each portion of superconducting wire to determine if one or more of the portions of superconducting wire are defective.

One or more of the following features may also be included. The test method may further include generating at least one VI curve from the plurality of VI data points. This generation may include superimposing at least a portion of the plurality of VI curves to form a composite VI curve. The composite VI curve may be analyzed to determine if one or more of the plurality of portions of superconducting wire is defective. A portion of superconducting wire may be deemed defective if the portion of superconducting wire is unacceptable for use in a fault current limiting circuit.

The method may further include generating a test acceptability curve that defines a superconducting defect. The method may also include analyzing at least a portion of each of the plurality of VI curves by comparing each of the plurality of VI curves to the test acceptability curve to identify at least one defective portion of the plurality of portions of superconducting wire. Further, if at least one defective portion of the plurality of portions of superconducting wire is identified, the method may include replacing the at least one defective portion with a splice.

In some implementations the method may be configured to operate over a wide range of values. For example, in some implementations, Ec may be approximately 1.00 μV/cm and Ex may be approximately 10 times Ec. Of course, numerous other values are also within the scope of the present disclosure.

In a second implementation of this disclosure, a testing system configured to analyze a superconducting wire is provided. The testing system may include a first testing device configured to perform a voltage/current (VI) test for each of a plurality of portions of superconducting wire. The VI test may include determining a plurality of VI data points for each of the plurality of portions of superconducting wire at a first VI datapoint of about (Ic (critical current), Ec (critical electric field)) and at a second VI datapoint of about (Ix, Ex). In some implementations Ex may be approximately equal to at least 10 times Ec and Ix may be approximately equal to the current resulting at that voltage drop. The testing system may further include a second testing device configured to analyze the plurality of VI data points for each portion of superconducting wire to determine if one or more of the portions of superconducting wire is defective.

One or more of the following features may also be included. The second testing device may be further configured to generate at least one VI curve from the plurality of VI data points by superimposing at least a portion of the plurality of VI curves to form a composite VI curve. The second testing device may be further configured to analyze the composite VI curve to determine if one or more of the plurality of portions of superconducting wire is defective. A portion of superconducting wire may be deemed defective if the portion of superconducting wire is unacceptable for use in a fault current limiting circuit.

The second testing device may be further configured to generate a test acceptability curve that defines a superconducting defect. The testing system may be further configured to analyze at least a portion of each of the plurality of VI curves. This analysis may include comparing each of the plurality of VI curves to the test acceptability curve to identify at least one defective portion of the plurality of portions of superconducting wire.

In some implementations Ec may be approximately 1.00 μV/cm and Ex may be approximately 10 times Ec. Of course, numerous other values are also within the scope of the present disclosure.

In a third implementation of this disclosure, a superconducting wire is described herein. The superconducting wire may be obtained via a process, which may include performing a voltage/current (VI) test for each of a plurality of portions of superconducting wire. The VI test may include determining a plurality of VI data points for each of the plurality of portions of superconducting wire at a first VI datapoint of about (Ic (critical current), Ec (critical electric field)) and at a second VI datapoint of about (Ix, Ex) wherein Ex is approximately equal to at least 10 times Ec and Ix is approximately equal to the current resulting at that voltage drop. The process may further include analyzing the plurality of VI data points for each portion of superconducting wire to determine if one or more of the portions of superconducting wire is defective. The process may further include removing a defective portion, if present.

One or more of the following features may also be included. The process may further include generating at least one VI curve from the plurality of VI data points. This may include superimposing at least a portion of the plurality of VI curves to form a composite VI curve. The composite VI curve may be analyzed to determine if one or more of the plurality of portions of superconducting wire is defective, and if so, determine if that defect is acceptable for the wire's application. A portion of superconducting wire may be deemed defective if the portion of superconducting wire is unacceptable for use in a fault current limiting circuit.

In some implementations, the process may further include generating a test acceptability curve that defines a defective portion of superconducting wire. The process may further include analyzing at least a portion of each of the plurality of VI curves by comparing each of the plurality of VI curves to the test acceptability curve to identify at least one defective portion of the plurality of portions of superconducting wire.

In a fourth implementation of this disclosure, a high temperature superconducting wire is disclosed. The high temperature superconducting wire may include a plurality of portions along its length. At least one of the portions may include a decreasing voltage to current ratio when a voltage/current (VI) test is performed for the portion of the superconducting wire. The VI test may include determining a plurality of VI data points at a first VI datapoint of about (Ic (critical current), Ec (critical electric field)) and at a second VI datapoint of about (Ix, Ex) wherein Ex is approximately equal to at least 10 times Ec and Ix is approximately equal to the current resulting at that voltage drop.

In a fifth implementation of this disclosure, a high temperature superconducting integrated fault current limiting cable is provided. The high temperature superconducting integrated fault current limiting cable may include a plurality of high temperature superconducting wires. The wires may include a plurality of portions along their lengths and at least one of the wires may include a wire portion with a decreasing voltage to current ratio when a voltage/current (VI) test is performed for the portion of the superconducting wire. The VI test may include determining a plurality of VI data points at a first VI datapoint of about (Ic (critical current), Ec (critical electric field)) and at a second VI datapoint of about (Ix, Ex) wherein Ex is approximately equal to at least 10 times Ec and Ix is approximately equal to the current resulting at that voltage drop.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a schematic diagram of a copper-cored HTS cable system installed within a utility power grid;

FIG. 2 is an isometric view of the copper-cored HTS cable of FIG. 1;

FIG. 3 is an isometric view of a hollow-core HTS cable;

FIG. 4 is a schematic diagram of the hollow-core HTS cable of FIG. 3 installed within a utility power grid;

FIG. 5A is a cross-sectional view of an HTS wire;

FIG. 5B is a cross-sectional view of an alternative embodiment HTS wire;

FIG. 6 is a schematic diagram of a utility power grid;

FIG. 7 is a schematic diagram of a testing system for analyzing HTS wire;

FIG. 8 shows the testing system of FIG. 7 in further detail;

FIG. 9 shows a side view of a section of HTS wire having individual portions;

FIG. 10 shows a method in accordance with an exemplary embodiment of the present disclosure;

FIG. 11 shows a method in accordance with yet another exemplary embodiment of the present disclosure;

FIG. 12 shows a diagram having a series of VI curves indicative of an “ideal” wire;

FIG. 13 shows a diagram having a series of VI curves indicative of an “ideal” wire;

FIG. 14 shows a composite voltage/current (VI) curve indicating the results of a VI test performed on the plurality of portions of HTS wire as compared with an “ideal” wire;

FIG. 15 shows yet another composite voltage/current (VI) curve indicating the results of a VI test performed on the plurality of portions of HTS wire; and

FIG. 16 is a flowchart of a method of testing HTS wire.

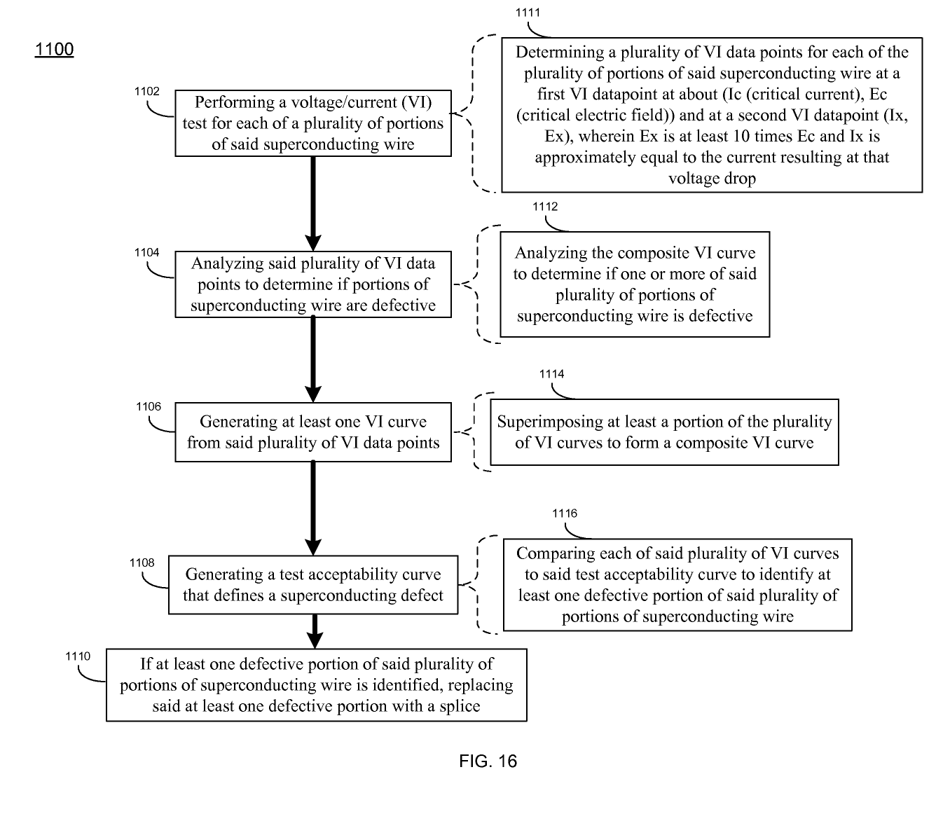

### DETAILED DESCRIPTION OF EXEMPLARY EMBODIMENTS

### Overview

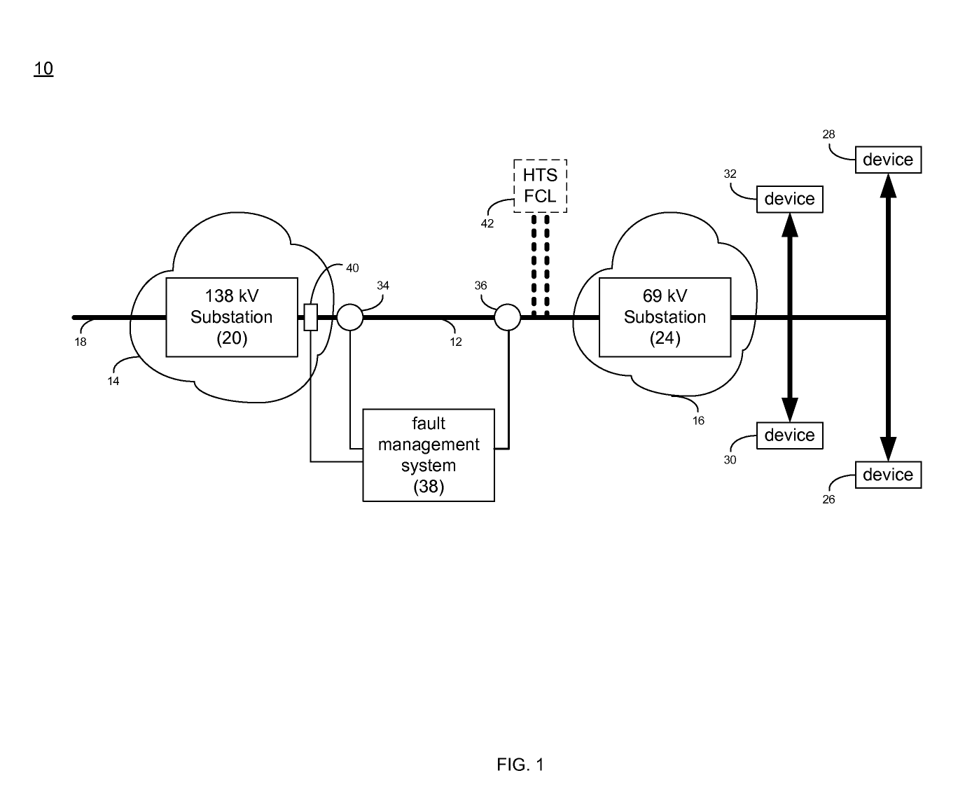

Referring to FIG. 1, a portion of a utility power grid 10 may include a high temperature superconductor (HTS) cable 12. HTS cable 12 may be hundreds or thousands of meters in length and may provide a relatively high current/low, or essentially zero resistance electrical path for the delivery of electrical power from generation stations (not shown) or imported from remote utilities (not shown).

The cross-sectional area of HTS cable 12 may only be a fraction of the cross-sectional area of a conventional copper core cable and may be capable of carrying the same amount of electrical current. As discussed above, within the same cross-sectional area, an HTS cable may provide three to five times the current-carrying capacity of a conventional AC cable; and up to ten times the current-carrying capacity of a conventional DC cable. As HTS technology matures, these ratios may increase.

As will be discussed below in greater detail, HTS cable 12 includes HTS wire, which may be capable of handling as much as one-hundred-fifty times or more of the electrical current of similarly-sized copper wire. Accordingly, by using a relatively small quantity of HTS wire (as opposed to a large quantity of copper conductors stranded within the core of a traditional AC cable), an HTS power cable may be constructed that is capable of providing three to five times as much electrical power as an equivalently-sized traditional copper-conductor power cable.

HTS cable 12 may be connected within a transmission grid segment 14 that carries voltages at a level of e.g., 138 kV and extends from grid segment 14 to grid segment 16, which may receive this voltage and transform it to a lower level of e.g., 69 kV. For example, transmission grid segment 14 may receive power at 765 kV (via overhead line or cable 18) and may include a 138 kV substation 20. 138 kV substation 20 may include a 765 kV/138 kV transformer (not shown) for stepping down the 765 kV power received on cable 18 to 138 kV. This “stepped-down” 138 kV power may then be provided via e.g., HTS cable 12 to transmission grid segment 16. Transmission grid segment 16 may include 69 kV substation 24, which may include a 138 kV/69 kV transformer (not shown) for stepping down the 138 kV power received via HTS cable 12 to 69 kV power, which may be distributed to e.g., devices 26, 28, 30, 32. Examples of devices 26, 28, 30, 32 may include, but are not limited to 34.5 kV substations.

The voltage levels discussed above are for illustrative purposes only and are not intended to be a limitation of this disclosure. Accordingly, this disclosure is equally applicable to various voltage and current levels in both transmission and distribution systems. Likewise, this disclosure is equally applicable to non-utility applications such as industrial power distribution or vehicle power distribution (e.g. ships, trains, aircraft, and spacecraft).

One or more circuit breakers 34, 36 may be connected on e.g., each end of HTS cable 12 and may allow HTS cable 12 to be quickly disconnected from utility power grid 10. Fault management system 38 may provide over-current protection for HTS cable 12 to ensure that HTS cable 12 is maintained at a temperature that is below the point at which HTS cable 12 may be damaged.

Fault management system 38 may provide such over-current protection by monitoring the current flowing in the segment of the utility grid to which HTS cable 12 is coupled. For example, fault management system 38 may sense the current passing through 138 kV substation 20 (using e.g., current sensor 40) and may control the operation of breakers 34, 36 based, at least in part, on the signal provided by current sensor 40.

In this example, HTS cable 12 may be designed to withstand a fault current as high as 51 kA with a duration of 200 ms (i.e., 12 cycles of 60 Hz power). The details of fault management system 38 are described in U.S. patent application Ser. No. 11/459,167, which was filed on 21 Jul. 2006, and is entitled Fault Management of HTS Power Cable. Typically, in order to withstand this level of fault current, the HTS cable may contain a significant amount of copper, which may help to carry the high fault current and thus protect the HTS wires. The copper is present to protect the HTS cable, but it has no significant current limiting effect because of its very low resistance.

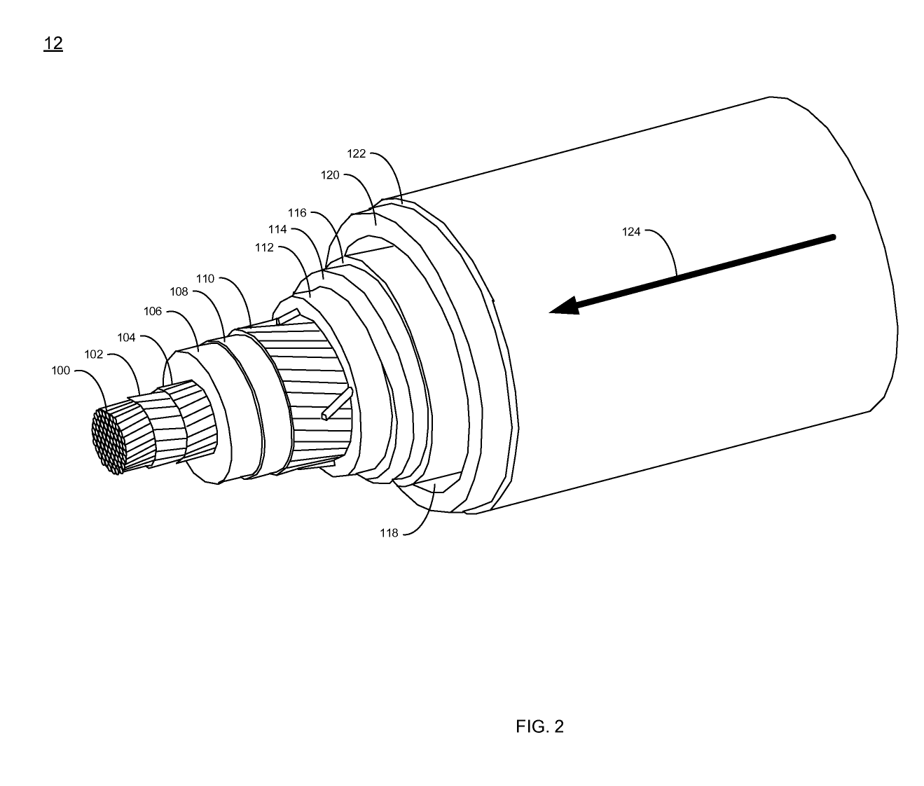

Referring also to FIG. 2, there is shown a typical embodiment of a single-phase copper-cored HTS cable 12 that may include stranded copper core 100 surrounded in radial succession by first HTS layer 102, second HTS layer 104, high voltage dielectric insulation layer 106, copper shield layer 108, HTS shield layer 110, coolant passage 112, inner cryostat wall 114, thermal insulation 116, vacuum space 118, outer cryostat wall 120 and an outer cable sheath 122. HTS layer 102 and HTS layer 104 may also be referred to as “phase conductors”. Copper shield layer 108 may alternatively be positioned on the outside of HTS shield layer 110. During operation, a refrigerant or liquid cryogen (e.g., liquid nitrogen, not shown) may be supplied from an external coolant source (not shown) and may be circulated within and along the length of coolant passage 112. All components of the cable are designed so as to enable flexibility of HTS cable 12. For example, stranded copper core 100 (upon which first HTS layer 102 and second HTS layer 104 are wound) is flexible. Accordingly, by utilizing flexible stranded copper core 100, an HTS cable 12 is realized that is continuously flexible along its length. Optionally, a corrugated metal former may be used to support the helically wound HTS wires, providing continuous flexibility along the length of the cable.

Additionally/alternatively, additional coaxial HTS and insulation layers may be utilized. For example, more than two layers of HTS wires may be used for a single phase. Also, three groups of HTS layers separated by insulation layers (not shown) may be utilized to carry three-phase power. An example of such a cable arrangement is the Triax HTS Cable arrangement proposed by Ultera (i.e., a joint venture of Southwire Company of Carrollton, Ga. and nkt cables of Cologne, Germany). Other embodiments of HTS cable 12 may include, but are not limited to: warm and/or cold dielectric configurations; single-phase vs. multi-phase configurations; and various shielding configurations (e.g., no shield and cryostat-based shielding).

Copper core 100 and copper shield layer 108 may be configured to carry fault currents (e.g., fault current 124) that may appear within cable 12. For example, when fault current 124 appears within cable 12, the current within HTS layers 102, 104 may dramatically increase to a level that exceeds the critical current level (i.e., I_{c}) of HTS layers 102, 104, which may cause HTS layers 102, 104 to lose their superconducting characteristics (i.e., HTS layers 102, 104 may go “normal”). A typical value for critical current level I_{c} is 4,242 Aₚₑₐₖ for a cable rated at 3000 Aᵣₘₛ (where Aᵣₘₛ refers to root-mean-square Amperes of current).

The critical current level in HTS materials may depend upon the choice of electric field level. Conventionally, the critical current level I_{c} is defined as an electric field level of 1 microvolt/cm, though lower values are also used. However, typical superconductors exhibit a transition region between the zero-resistance (i.e., superconducting) and fully-resistive (i.e., non-superconducting) states as a function of current level. Conductor losses resulting from operation in this transition region are below those of the fully-resistive state. Therefore, in practice, portions of conductor in the HTS cable may switch to the fully resistive state at a critical current level that is a factor (“f”) times the conventional critical current level I_{c} defined by the 1 microvolt/cm criterion. In meander line wires with YBCO thin films, this factor was determined to be approximately 2, but it was observed to vary somewhat with time. See Switching Behavior of YBCO Thin Film Conductors in Resistive Fault Current Limiters by H.-P. Kraemer et al., IEEE Trans. on Applied Superconductivity, vol. 13, No. 2, June 2003, pp. 2044-7. The f-factor for HTS wires with similar YBCO thin films is anticipated to be in a similar range (e.g., 1-4).

Accordingly, when the product of the critical current level (as defined above) and the f-factor is exceeded, the resistance of HTS layers 102, 104 may increase significantly and may become comparatively high (i.e., when compared to copper core 100). As the current passing through a plurality of parallel conductors is distributed inversely with respect to the resistance of the individual conductors, the majority of fault current 124 may be diverted to copper core 100, which is connected in parallel with HTS layers 102, 104. This transmission of fault current 124 through copper core 100 may continue until: fault current 124 subsides; or the appropriate circuit breakers (e.g., circuit breakers 34, 36) interrupt the transmission of fault current 124 through HTS cable 12.

Overheating of the HTS conductors in HTS cable 12 may be avoided by two benefits provided by the copper core 100. First, by redirecting fault current 124 (or at least a portion thereof) from HTS layers 102, 104 to copper core 100, the overheating of the HTS conductors in HTS cable 12 may be avoided. Second, the added heat capacity of copper core 100 reduces the temperature rise in HTS layers 102 and 104. In the event that fault current 124 (or at least a portion thereof) was not redirected from HTS layers 102, 104 to copper core 100, fault current 124 may heat the HTS conductors in HTS cable 12 significantly due to the high resistance of HTS layers 102, 104, which may result in the formation of gaseous “bubbles” of liquid nitrogen (i.e., due to liquid nitrogen being converted from a liquid state to a gaseous state within coolant passage 112). Unfortunately, the formation of gaseous “bubbles” of liquid nitrogen may reduce the dielectric strength of the dielectric layer and may result in voltage breakdown and the destruction of HTS cable 12. For warm dielectric cable configurations (not shown), fault current not redirected away from HTS layers 102, 104 may simply overheat and destroy HTS layers 102, 104.

Examples of HTS cable 12 may include but are not limited to HTS cables available from Nexans of Paris France; Sumitomo Electric Industries, Ltd., of Osaka, Japan; and Ultera (i.e., a joint venture of Southwire Company of Carrollton, Ga. and NKT cables of Cologne, Germany).

While copper core 100 redirects fault currents (or portions thereof) around HTS layers 102, 104, there are disadvantages to utilizing such an “internal” copper core. For example, copper core 100 may require HTS cable 12 to be physically larger and heavier, which may result in increased cost and greater heat retention within HTS cable 12. Accordingly, more refrigeration may be required to compensate for the additional heat retention, resulting in higher overall system and operating costs. Moreover, the increased heat capacity of copper core 100, and the thermal resistance between the HTS layers 102, 104, and the coolant due to the dielectric layer may greatly increase recovery times should the energy of a fault current increase the temperature beyond the point where superconductivity can be maintained in HTS layers 102, 104. For example, in the event that a fault current is redirected through copper core 100, it may take several hours for the refrigeration system (not shown) to cool down HTS cable 12 to within the appropriate operating temperature range (e.g., 65-77° Kelvin). The time required to cool down HTS cable 12 to within the operating range of the cable is commonly referred to as the “recovery time”, which may be required by utilities to be as short as possible (e.g. seconds). Alternatively, a standalone fault current limiter may be used with HTS cable 12 to limit fault currents; however this has the disadvantage of requiring another large and costly piece of electrical equipment to be installed in the substation linked to HTS cable 12.

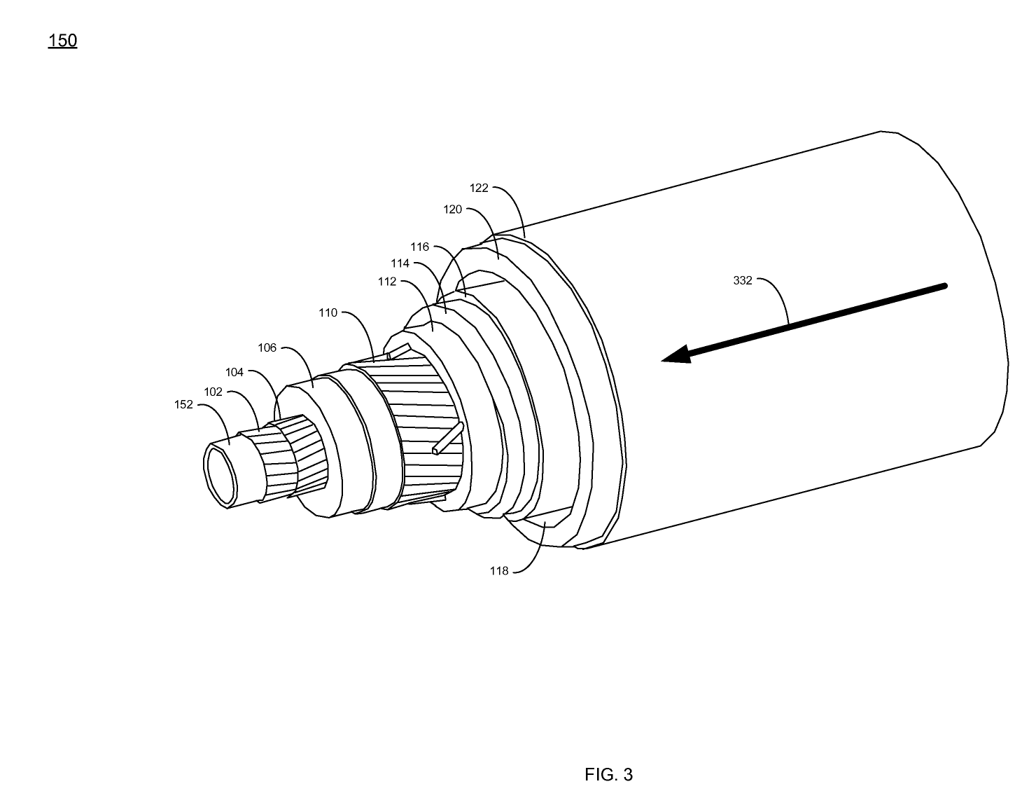

Referring to FIG. 3, there is shown a flexible, hollow-core HTS cable 150. While HTS cable 150 may include various components of prior art copper-cored HTS cable 12, HTS cable 150 does not include stranded copper core 100 (FIG. 2), which was replaced with a flexible hollow core (e.g., inner coolant passage 152). An example of inner coolant passage 152 may include, but is not limited to, a flexible, corrugated stainless steel tube. All copper shield layers may be removed as well. A refrigerant (e.g., liquid nitrogen) may flow through inner coolant passage 152.

In a fashion similar to that of copper-cored HTS cable 12, inner coolant passage 152 may be surrounded in radial succession by first HTS layer 102, second HTS layer 104 (usually helically wound with the opposite helicity of layer 102), high voltage dielectric insulation layer 106, HTS shield layer 110, coolant passage 112, inner cryostat wall 114, thermal insulation 116, vacuum space 118, outer cryostat wall 120 and an outer cable sheath 122. During operation, a refrigerant (e.g., liquid nitrogen, not shown) may be supplied from an external coolant source (not shown) and may be circulated within and along the length of coolant passage 112 and inner coolant passage 152. An alternative coolant (e.g., liquid neon or liquid hydrogen) may be used in the case of lower transition temperature materials like MgB₂.

As with HTS cable 12, all components of HTS cable 150 are designed so as to enable flexibility continuously along the length of the cable. For example and as discussed above, inner coolant passage 152 (upon which first HTS layer 102 and second HTS layer 104 are wound) is flexible. Accordingly, by utilizing flexible inner coolant passage 152, a flexible HTS cable 150 is realized.

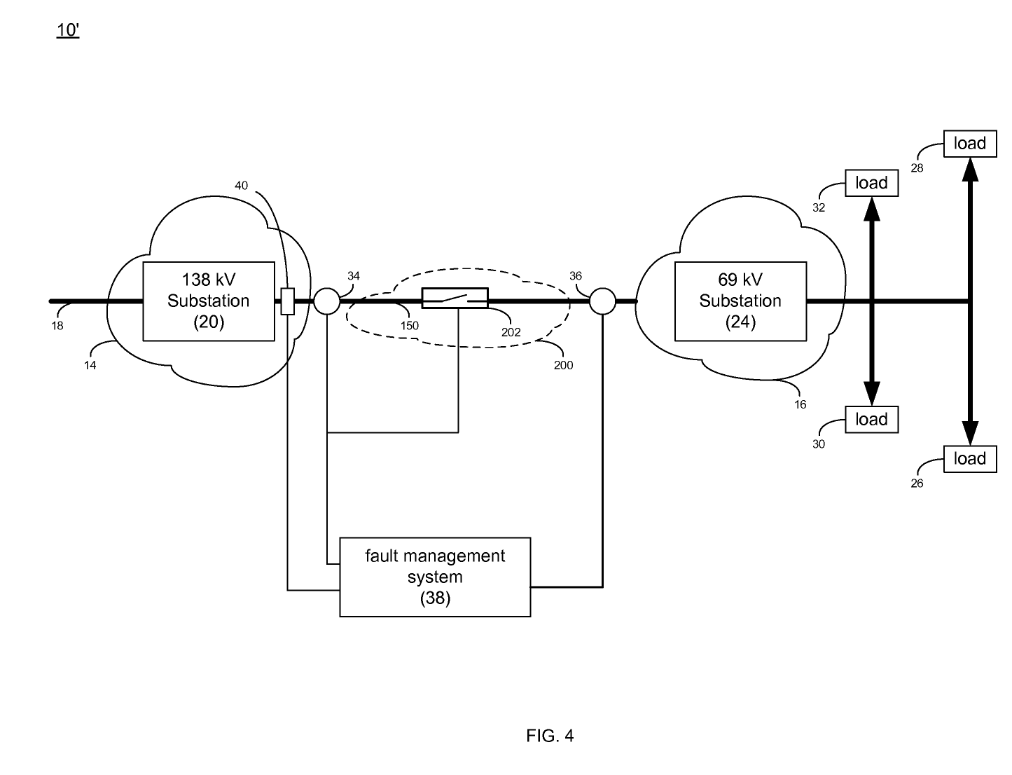

Referring also to FIG. 4, utility power grid portion 10′ may include flexible, long-length HTS cable 150. Here, long-length is defined as greater than 200 m. It may also include a conventional (i.e. non-superconducting cable, not shown) or cables, connected in parallel with HTS cable 150. An example of the conventional cable may include but is not limited to a 500 kcmil, 138 kV Shielded Triple Permashield (TPS) power cable available from The Kerite Company of Seymour, Conn. The conventional cables may be existing cables in a retrofit application where HTS cable 150 is being added to replace one or more conventional cables to e.g., increase the power capacity of an electrical grid. Alternatively, the conventional cable may be a new conventional cable that is installed concurrently with HTS cable 150 and interconnected with appropriate bus work and circuit breakers.

HTS cable 150 and/or additional HTS cables (not shown) may be included within superconducting electrical path 200, which may include a portion of a utility power grid. Further, superconducting electrical path 200 may include other superconducting power distribution devices, such as buses (not shown), transformers (not shown), fault current limiters (not shown), and substations (not shown).

A fast switch assembly 202 may be coupled in series with HTS cable 150. An example of fast switch assembly 202 is a 138 kV Type PM Power Circuit Breaker manufactured by ABB Inc. of Greensburg, Pa. Fast switch assembly 202 (e.g., a switch capable of opening in 4 cycles) may be controllable by fault management system 38. For example, upon sensing fault current 124 (FIG. 3), fault management system 38 may open fast switch assembly 202, resulting in HTS cable 150 being essentially isolated from fault current 124. For multiphase power, a plurality of fast switch assemblies 202 may be utilized. Alternatively, some fast switch assemblies or circuit breakers are built as a single three-phase device. Fast switch assembly 202 may be reclosed after a time sufficient to allow HTS cable 150 to recover to its superconducting state. If existing utility circuit breakers 34, 36 switch quickly enough to meet the heating requirements discussed below, fast switch assembly 202 may not be required.

The conventional cable (not shown) and/or additional conventional cables (not shown) may be included within a non-superconducting electrical path, which may include a portion of a power utility grid. Further, the non-superconducting electrical path may include other power distribution devices, such as buses (not shown), transformers (not shown), fault current limiters (not shown), and substations (not shown). The non-superconducting electrical path may be maintained at a non-cryogenic temperature (e.g., a temperature of at least 273 K, which corresponds to 0° C.). For example, the non-superconducting electrical path may not be cooled and, therefore, may assume ambient temperature.

As will be discussed below in greater detail, by removing copper core 100 (FIG. 2) and copper shield layer 108 (FIG. 2) from the inside of the flexible, long-length HTS cable 150 and by controlling the impedance of HTS cable 150, HTS cable 150 may be physically smaller, which may result in decreased fabrication cost and lower heat loss from HTS cable 150. Accordingly, HTS cable 150 may require less refrigeration (when compared to copper-cored HTS cable 12) and may result in lower overall system and operating costs. Further, by removing copper core 100 from the inside of HTS cable 150, the heat capacity of HTS cable 150 and the thermal resistance between HTS layers 102, 104 and the coolant may both be reduced, thus allowing for quicker recovery times in the event that fault current 124 increase the temperature of HTS cable 150 beyond the point where superconductivity may be maintained in HTS layers 102, 104. By removing copper core 100 from the inside of the flexible, long-length HTS cable 150 and by controlling the impedance of HTS cable 150, one can incorporate fault current limiting functionality directly into HTS cable 150, thus removing the need for a separate standalone fault current limiter if one wants to protect the HTS cable or downstream utility equipment from fault currents.

### HTS Cable and Fault Current Limiters

Referring again to FIG. 1, if a fault current within grid section 10 causes the current flowing through HTS cable 12 to rise beyond the limits of conventional circuit breakers 34, 36, an HTS FCL device 42 (shown in phantom) or conventional reactor technology (not shown) may be incorporated within grid section 10 to limit the amplitude of the fault current flowing through HTS cable 12 to a level that conventional circuit breakers 34, 36 can interrupt. Under normal conditions, when nominal current levels are flowing in grid section 10, HTS FCL device 42, which is connected in series with the power flow, may be designed to introduce very low impedance into the grid (compared to other grid impedances). However, when a fault current appears in grid section 10, the current causes the superconductor in HTS FCL 42 to instantaneously go “normal” or non-superconducting (i.e., resistive), and this adds a very large impedance into grid section 10. HTS FCL 42 may be designed to limit the fault current to a predetermined level that is within the interrupting capability of conventional circuit breakers 34, 36.

Standalone HTS FCL devices 42 are being developed by various companies, including American Superconductor Corporation (of Westboro, Mass.) in conjunction with Siemens AG (of Germany). Unfortunately, adding HTS FCL device 42 to grid section 10 may be costly and may require a significant amount of space to accommodate device 42, which may be difficult to accommodate, especially in urban areas. Short busbars or modules with fault current limiting capability are being developed by various companies, including Nexans (of France) and EHTS (of Germany). While fault current limiting busbars may have certain applications, they do not provide the sought-after high capacity, low footprint and flexibility that is provided by long-length continuously flexible cables for transmission and distribution applications.

An HTS device e.g. continuously flexible, long-length HTS cable 150 (FIG. 3), when properly designed, may be used as a fault current limiter itself without the need to incorporate a separate HTS FCL, such as HTS FCL device 42 (FIG. 1). By controlling e.g., the normal-state (resistive) impedance of HTS cable 150, the HTS cable itself may be utilized to obtain the desirable effects (e.g., attenuation of fault currents) of a typical standalone HTS FCL device (e.g., HTS FCL 42) while avoiding the undesirable effects (e.g., cost and size) of the typical standalone HTS FCL device. Specifically and as will be discussed below in greater detail, if the length of HTS cable 150 is sufficiently long and if HTS cable 150 is manufactured to exhibit desired impedance characteristics, continuously flexible, long-length HTS cable 150 alone may provide significant attenuation of fault current 124 (FIG. 3) without heating to the point to create gas bubbles in the liquid cryogen and risking dielectric breakdown.

### Overview of Fault Current Limiting (FCL) HTS Cable and Design of HTS Wire for FCL Cable

As will be discussed below in greater detail, by controlling various parameters of flexible long-length HTS cable 150 (e.g., the electrical resistivity and stabilizer thickness of the HTS wires within cable 150), an HTS cable may be realized that simultaneously 1) provides the required net resistance to achieve significant reduction of fault current in the cable, and 2) maintains the fault-current-induced temperature rise throughout HTS cable 150 at a level that is below a maximum value that prevents the bubbling of the liquid nitrogen coolant circulating within the cable. As discussed above, the formation of gaseous “bubbles” of liquid nitrogen may reduce the dielectric strength of the dielectric layer of HTS cable 150 and may result in voltage breakdown and the destruction of HTS cable 150.

Electrical resistivity, which may also be known as specific electrical resistance, is a measure of how strongly a material opposes the flow of electric current. Specifically, a low electrical resistivity may indicate a material that readily allows for the movement of electrical charge. A convenient measure of resistivity is microOhm-cm.

As will be discussed below in greater detail, the structure of HTS cable 150 and the design of the HTS wire within HTS cable 150 differ fundamentally from the designs that have been proposed for standalone HTS FCLs or fault-current-limiting busbars.

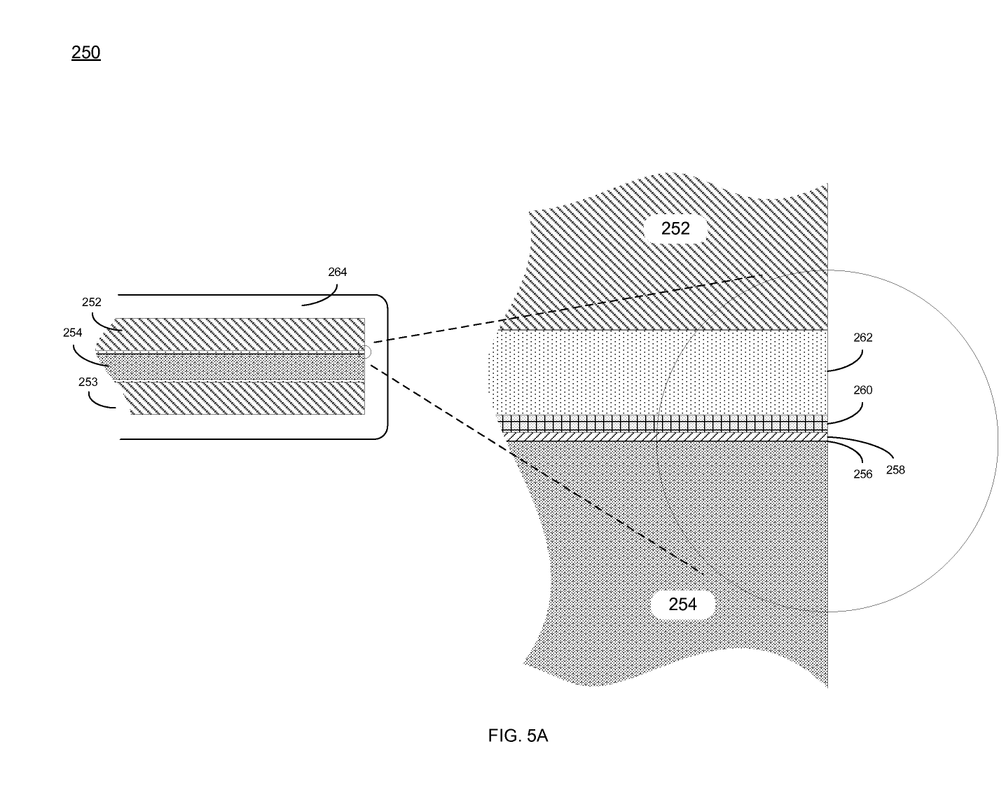

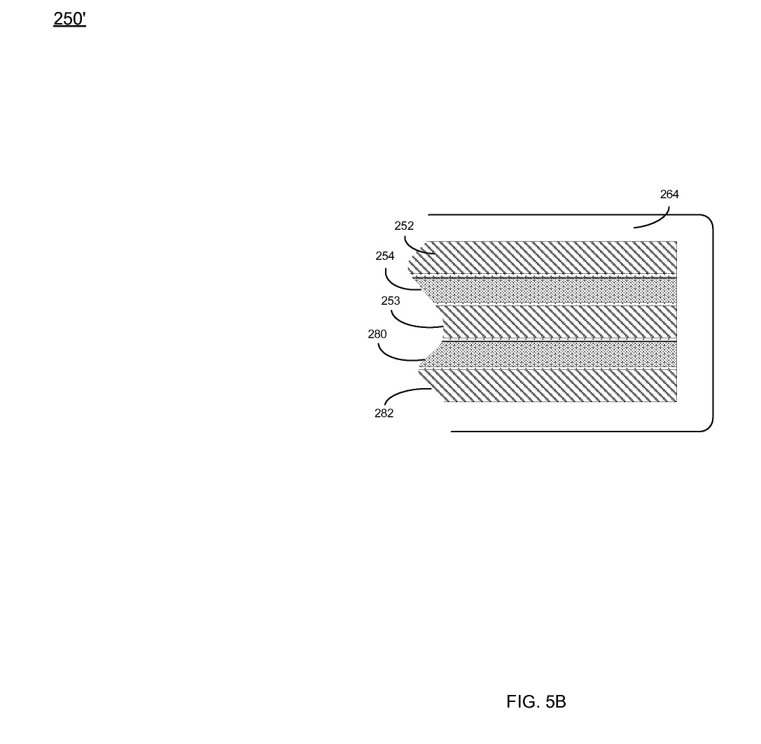

Referring also to FIG. 5, there is shown a cross-sectional view of one HTS wire 250 used to construct HTS layers 102, 104 of fault-current-limiting HTS cable 150. This wire architecture may also be called a “coated wire” architecture because a thin layer of superconductor (i.e., an HTS layer) is coated onto a buffered substrate. Typically, the HTS layer comprises the superconductor YBCO, as defined earlier, in particular the composition YBa₂Cu₃O₇ with possible substitutions of rare earth elements for Y It is understood that the overall composition may differ from this composition because impurity phases may be present in the layer. Other HTS materials can also be used in a coated conductor architecture.

In this example, HTS wire 250 used in HTS layers 102, 104 is shown to include two stabilizer layers 252, 253 and substrate layer 254. An example of substrate layer 254 may include but is not limited to nickel-tungsten, stainless steel and Hastelloy. Positioned between stabilizer layer 252 and substrate layer 254 may be buffer layer 256, HTS layer 258 (e.g., an yttrium-barium-copper-oxide—YBCO—layer), and cap layer 260. An example of buffer layer 256 is the combination of yttria, yttria-stabilized zirconia, and cerium oxide (CeO₂), and an example of cap layer 260 is silver. A solder layer 262 (e.g., a SnPbAg layer) may be used to bond stabilizer layers 252 and 253 to cap layer 260 and substrate layer 254.

In addition to the above-described wire configuration, other wire configurations are considered to be included within the scope of this disclosure. For example, a single stabilizer layer may be used. Alternatively, a second HTS layer (with its buffer and cap layers, not shown) may be located between second stabilizer layer 253 and the underside of substrate 254. Optionally, the HTS wire may consist of two stabilizer layers positioned on the outside of the HTS wire, with two substrates (each with a buffer layer, an HTS layer, and a cap layer), separated by a third stabilizer layer positioned between the two substrate layers. A solder layer may be used to facilitate any of the required bonds (except possibly between substrate layer 254, buffer layer 256, HTS layer 258 and cap layer 260).

Referring also to FIG. 5B, there is shown HTS wire 250′, which is an alternative embodiment of HTS wire 250. HTS wire 250′ may include a second substrate layer 280 positioned between second stabilizer layer 253 and third stabilizer layer 282. Positioned between stabilizer layer 253 (and/or stabilizer layer 282) and substrate layer 280 may be a buffer layer, an HTS layer (e.g., an yttrium-barium-copper-oxide—YBCO—layer), a cap layer, and a solder layer.

### The Stabilizer Layer of HTS Wire

The HTS wire functions most effectively and economically as a fault current limiter if the heat capacity of the HTS wire is high and the electrical resistivity of the HTS wire is at an optimal level. Stabilizer layer 252 may be essential to achieving these properties. Examples of alloys that may be particularly well suited for stabilizer layer 252 are low alloy brasses (e.g., Cu—Zn), with e.g., Zn in the 3-40% wt range, as well as possibly other brass alloys based on e.g., the Cu—Sn alloy system. Alloys with resistivities in the 0.8-20 micro-ohm cm. range in the 77-110 K temperature range may be optimal. Particular brass alloys may include but are not limited to brass 210 (95 Cu-5 Zn), 220 (90 Cu-10 Zn), and 230 (85 Cu-15 Zn), 240 (80 Cu-20 Zn) and 260 (70 Cu-30 Zn). Other copper-based alloys may include e.g., the Monel series (Cu—Ni), which may also provide the above-described range of resistivities. Cu—Ni alloys or others with a magnetic transition in the 70-110 K range may be used and may have the additional advantage of a large specific heat peak in this temperature range. However, care should be taken with these alloys to minimize magnetic AC losses by minimizing coercivity.

### Encapsulants for HTS Wire

Additional specific heat may be provided by optionally adding a poorly-conducting “insulator” layer deposited or wrapped around the stabilized HTS wire to encapsulate it. This poorly-conducting insulator layer may be referred to as encapsulant 264. Encapsulant 264 may form a liquid-impermeable layer of generally limited heat transfer coefficient to delay heat introduction into the surrounding liquid coolant (e.g., liquid nitrogen), thus allowing the temperature of the HTS wire to thermalize, i.e., become more uniform across its cross section and thus minimize the occurrence of hot spots and gas bubble formation in the liquid coolant. The surface of the HTS wire may also be optimized (e.g., with surface features and surface chemistry) to inhibit the onset of liquid coolant bubbling or boiling.

Encapsulant 264 may be a polymer (e.g., polyethylene, polyester, polypropylene, epoxy, polymethyl methacrylate, polyimides, polytetrafluoroethylene, and polyurethane) that includes common electrically insulating materials. The thickness of encapsulant 264 may be selected to balance the need to cool the HTS wire by heat transfer into the surrounding liquid coolant and the need to maximize the temperature of the HTS wire without forming gas bubbles within the surrounding liquid coolant. A general thickness range for encapsulant 264 is 25-300 micrometers, and a desirable thickness range for encapsulant 264 is 50-150 micrometers.

Additional information regarding HTS wire, including a more detailed description of the stabilizer layer and encapsulants for HTS wire may be found in U.S. patent application Ser. No. 11/688,817, which is incorporated by reference herein in its entirety.

### Operation in a Utility Grid

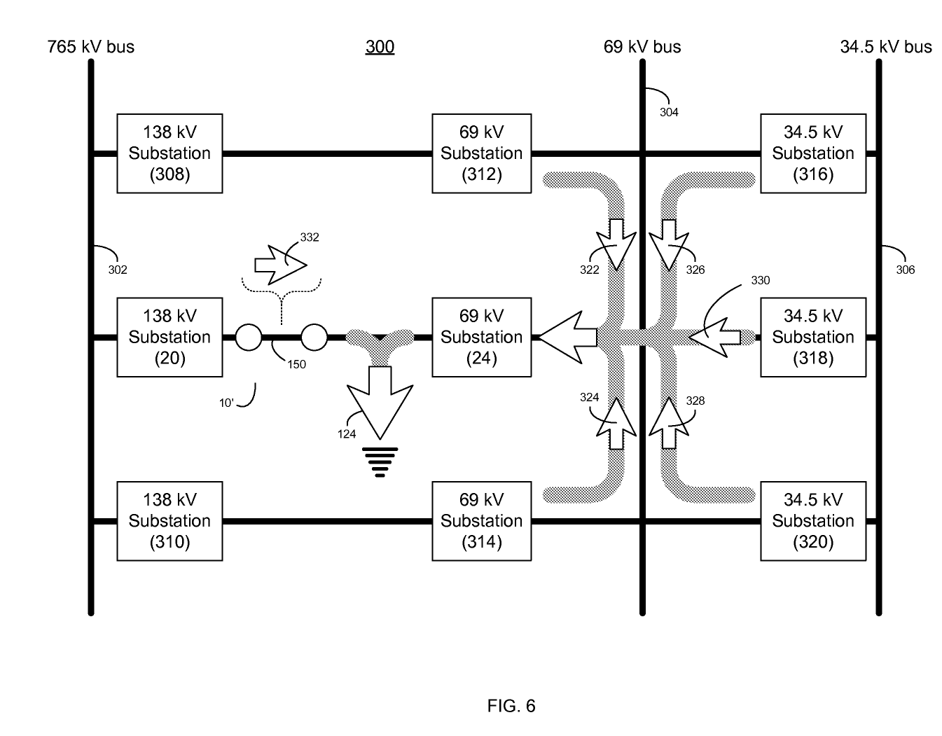

Referring also to FIG. 6, the operation of fault current limiting HTS cable 150 within the context of utility power grid 300 is shown. In this particular example, utility power grid 300 is shown to include 765 kV bus 302, 69 kV bus 304, and 34.5 kV bus 306. Further, utility power grid 300 is shown to include three 138 kV substations 20, 308, 310, each of which provides power to 69 kV bus 304 through three 69 kV substations 24, 312, 314. Three 34.5 kV substations 316, 318, 320 may provide power from 69 kV bus 304 to 34.5 kV bus 306. The fault current limiting HTS cable 150 is shown coupled between substations 20 and 24.

When a fault current (e.g., fault current 124) is present within utility power grid 300, various current components 322, 324, 326, 328, 330, 332 (i.e., the portion of fault current 124 passing through HTS cable 150) may flow from all interconnected substations through all available paths to feed fault current 124, which may appear as a very large load placed on utility power grid 300. When calculating the current components realizable during a fault condition, fault current 124 may be modeled as a short-circuit to ground.

### Testing of HTS Wire

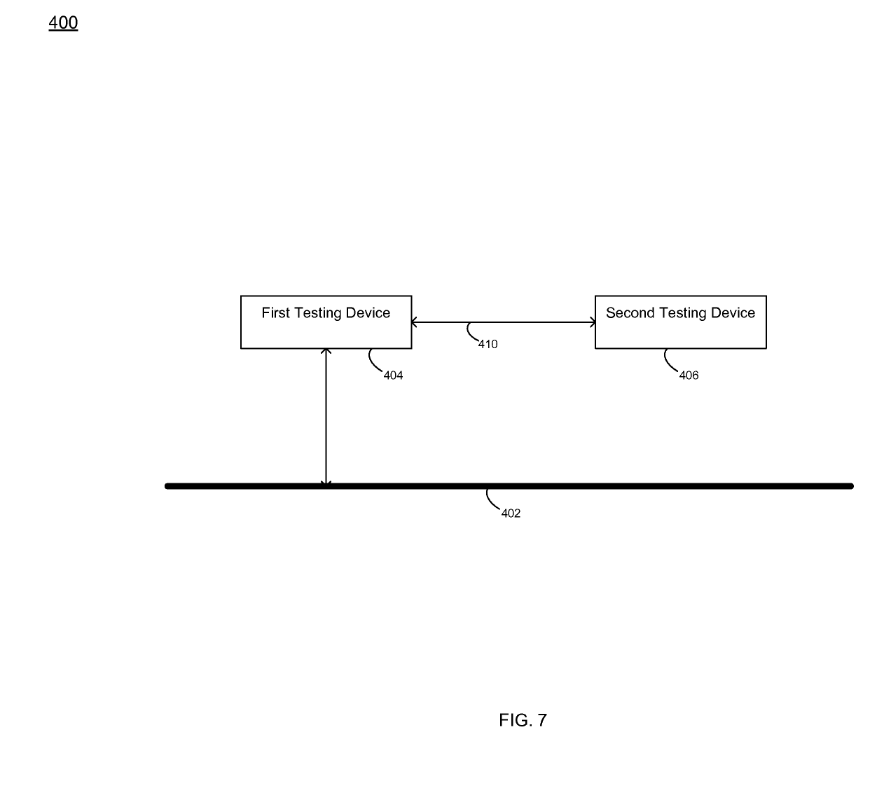

Referring now to FIG. 7, a system 400 for testing HTS wire is provided. System 400 may be used to test numerous different types of HTS wire including, but not limited to, the arrangements shown in FIGS. 5A and 5B. In this particular example, system 400 may be configured to perform testing operations on HTS wire 402. Typical commercial lengths of wire will be in the range of 1000 m, but the disclosure contained herein may be applied to different lengths and varying types of HTS wire (e.g., the HTS layers shown in the configurations of FIGS. 2 and 3).

Testing system 400 may include a first testing device 404 configured to perform a voltage and/or current (VI) test on HTS wire 402. As such, first testing device 404 may be configured to generate a voltage or current signal and to apply that signal to HTS wire 402. Any resulting variations across HTS wire 402 may then be measured by first testing device 404 and the measurement results may be transmitted along communication line 410 to second testing device 406.

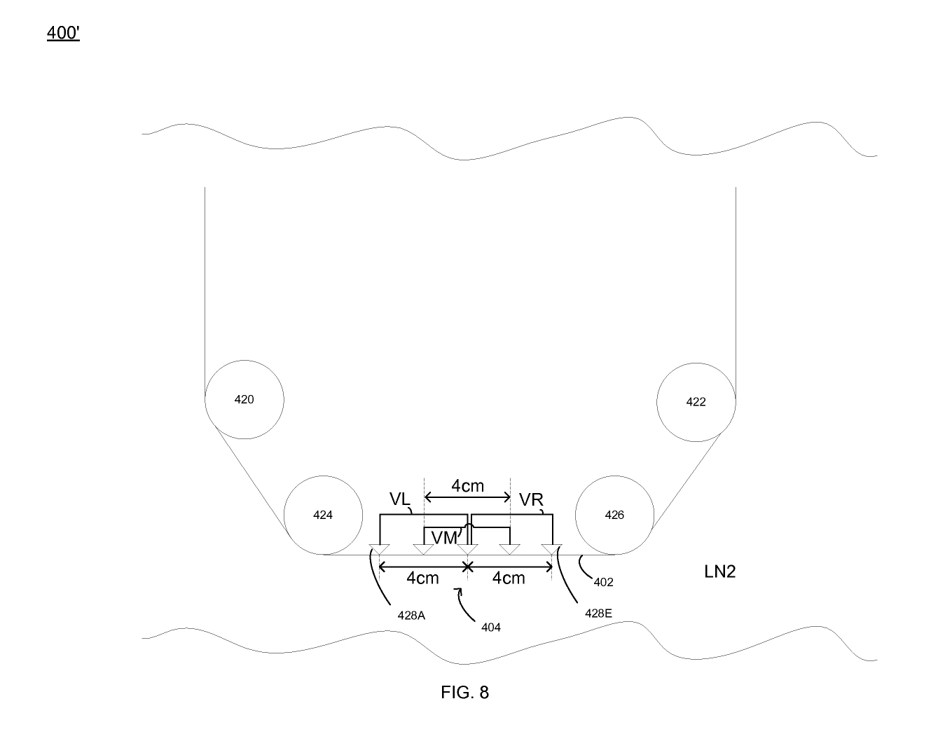

Referring now to FIG. 8, a more detailed schematic depicting aspects of testing system 400′ is shown. Testing system 400′ shows HTS wire 402 in electrical communication with first testing device 404. First testing device 404 may include a number of different components including, but not limited to, current contacts 420 and 422, guides 424 and 426, and probes 428A-E. It should be noted that while five probes are used in this example any suitable number of probes could be used.

In some implementations, a current may be injected into HTS wire 402 by mechanically contacting HTS wire 402 with a conductor such as current contacts 420 and 422. Current contacts 420 and 422 may be configured in a variety of different arrangements. For example, current contacts 420 and 422 may include copper wheels, which may be used to create an electrical connection with HTS wire 402. In this example, the current injection may occur in a liquid nitrogen environment (LN2). Here, a voltage measurement may be taken and the electric field may be calculated as the result of this measured voltage divided by the distance between the specific probes that are used, e.g., the distance between probes 428A and 428E. Although this particular example, describes the application of a current to HTS wire 402, it should be noted that a voltage may be applied as well in which case the current would be measured by probes 428A-E.

In this particular example, the current wave form may take the form of a ramp, but is not limited to a ramp. The waveform could be a triangle pulse, square pulse, sinusoidal pulse, or any other wave function or combination of wave functions. This ramp may extend from 0 to 500 Amps in times ranging from 10 to 500 ms. This may then be followed by a hold time of sufficient length to ensure that the wire has time to cool, i.e., no current is applied and no more heating occurs. The ramp rate may then be chosen to ensure isothermal conditions. All data fed into second testing device 406 must be free of heating effects in order to avoid double count heat generation. The duration of the ramp and the duration of the post ramp cooling time may be selected to establish isothermal measurement conditions. In this particular example, any given portion of HTS wire 402 may receive approximately 50 pulses prior to measurement. Of course, the numerical quantities described herein are merely provided for exemplary purposes, as other values may be used without departing from the scope of the present disclosure.

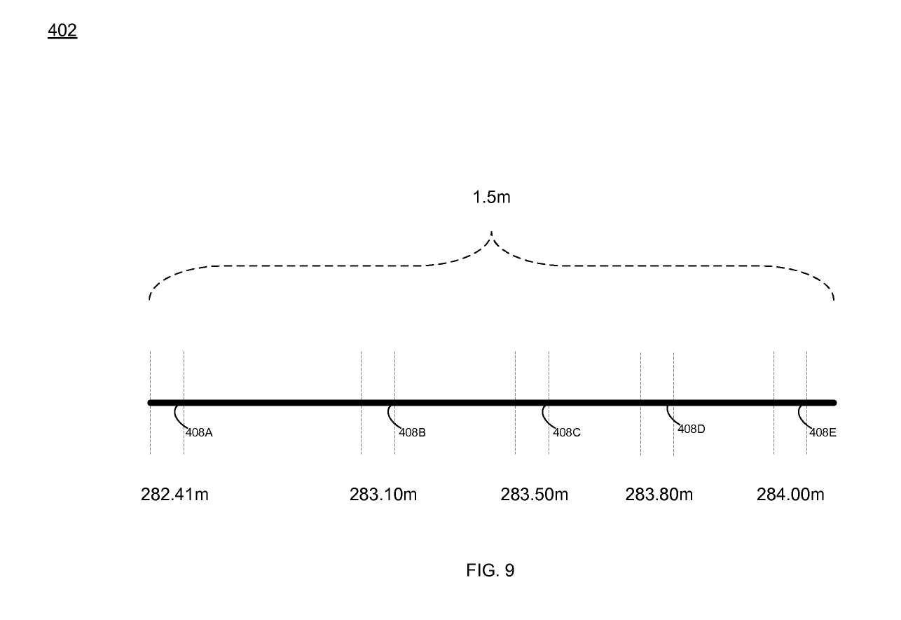

In some implementations, guides 424 and 426 may operate as voltage contacts. In this way, guides 424 and 426 may rely on friction to establish the electrical connection with HTS wire 402. In one example, the voltage contacts may be spaced 4 cm apart as described below in greater detail in FIG. 9. Other distances may also be used. This spacing may be selected to account for design trade off's such as line speed and background noise.

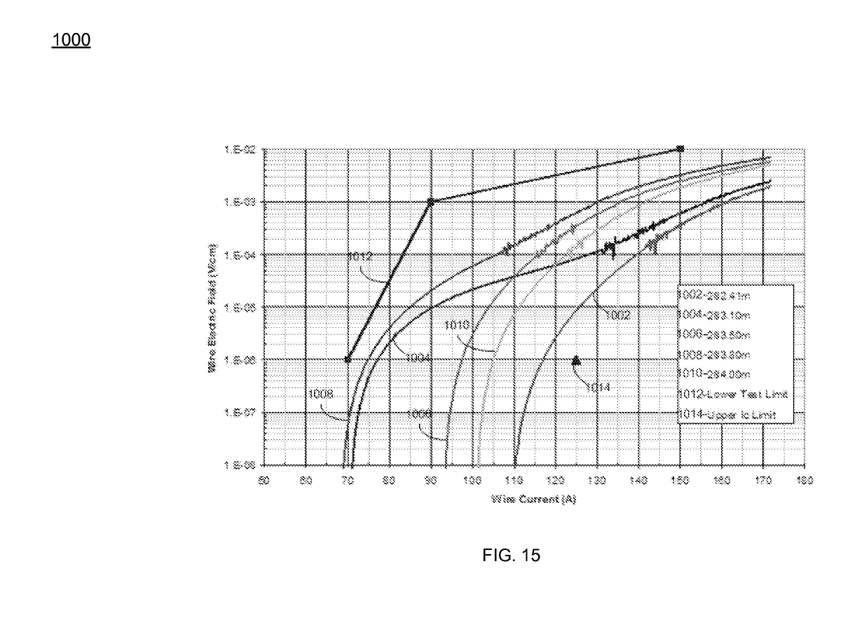

Referring now also to FIG. 9, an section of HTS wire 402 having a 1.5 m length divided into a plurality of portions 408A-E is provided. For the purposes of this example, each of portions 408A-E may have a length of approximately 4 cm. As noted above, these distances are noted merely for exemplary purposes as they have been selected to further the understanding of the present disclosure. In this particular example, five distinct portions 408A-E of HTS wire 402 are shown. First testing device 404 may be configured to take measurements over these portions of HTS 402 wire and to send the results to second testing device 406. In this example, measurements were taken at the 282.41 m, 283.10 m, 283.50 m, 283.80 m, and 284.00 m locations of HTS wire 402, which correspond to portions 408A, 408B, 408C, 408D, and 408E respectively. These measurements may be relayed to second testing device 406 via communications link 410 for subsequent processing and analysis. Preferably, the voltage measurements may be normalized to provide an electric field (E) measurement of V/cm and a composite VI curve constructed from a plurality of VI datapoints resulting from these measurements is shown in FIG. 15, which is described in further detail below. In some cases, the datapoints used could be voltage and current datapoints. When the term VI and/or VI datapoints are used in this application, it is meant to include both voltage (V) and electric field (E).

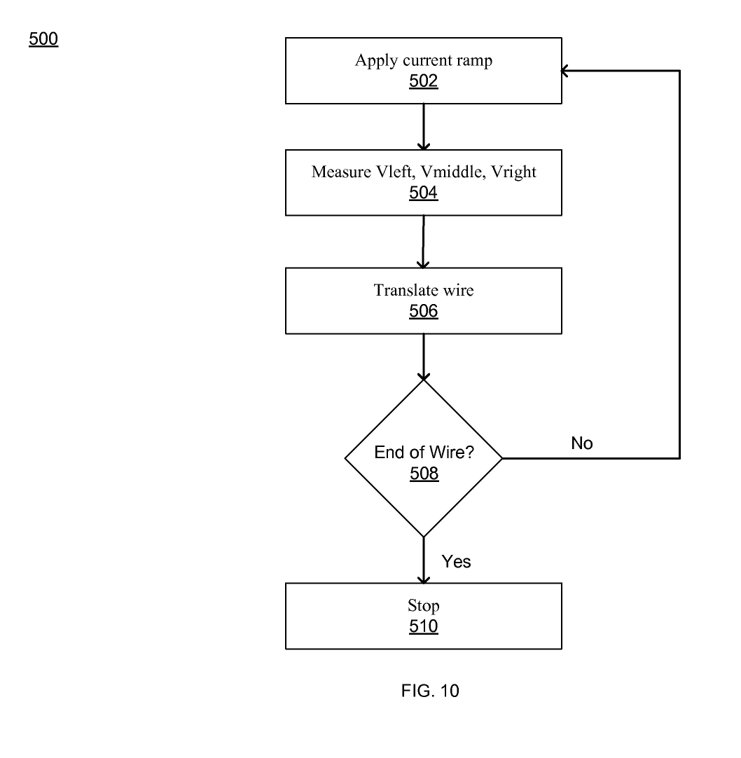

Referring now also to FIG. 10, a method 500 for measuring HTS wire is provided. First testing device 404 may be configured to apply a current ramp (502) while the resultant voltage signals are recorded using a number of sensing devices 428A-428E (e.g., probes) (504). The first sensing device may be a low range sensing device that may be configured to gather VI datapoints to determine the electric field (E) over the 10⁻⁶ to 10⁻⁴ volts/cm range. Similarly, the second sensing device may be used to gather the VI datapoints from the 10⁻⁴ to 10⁻² range. If VI datapoints in the 10⁻² to 10^{- range} are desired a third sensing device may also be used. In the case of the 10⁻⁴ to 10⁻² volts/cm range the sensor gains may be selected such that the 10⁻³ and 10⁻² data is gathered in the middle of the sensor range in order to ensure greater accuracy. The first, second, and third sensing devices may be formed using differing combinations of probes 428A-428E.

After the VI datapoints are gathered the current may be removed for a brief period (e.g., approximately 250 ms) while the sample translates 2 cm (506). The next series of VI datapoints may be determined and then the wire may translate another 2 cm and the next VI datapoints are determined until the end of HTS wire 402 is reached (508). This methodology may allow for every integral section of wire to be measured multiple times.

In some implementations, testing system 400 may include an additional two sets of voltage contacts that may be used to gather VI datapoints. The middle set may include two voltage sensor ranges that gather similar data to the first set. At this time the third set of voltage contacts may have the 10⁻⁶ to 10⁻⁴ volts/cm range set up for data gathering. However, a voltage contact having a higher e-field range may also be used. All three sets voltage contacts may be used to cross check the results. Other configurations are also envisioned.

As shown in FIG. 7, HTS wire 402 and first testing device 404 may also be operatively connected to second testing device 406, which may be configured to receive and analyze the measured VI datapoints. That is, after all the data is gathered for HTS wire 402 a data file may be created and/or transmitted for post processing within second testing device 406. In some embodiments, the first and second testing devices 404, 406 may be incorporated within a single device.

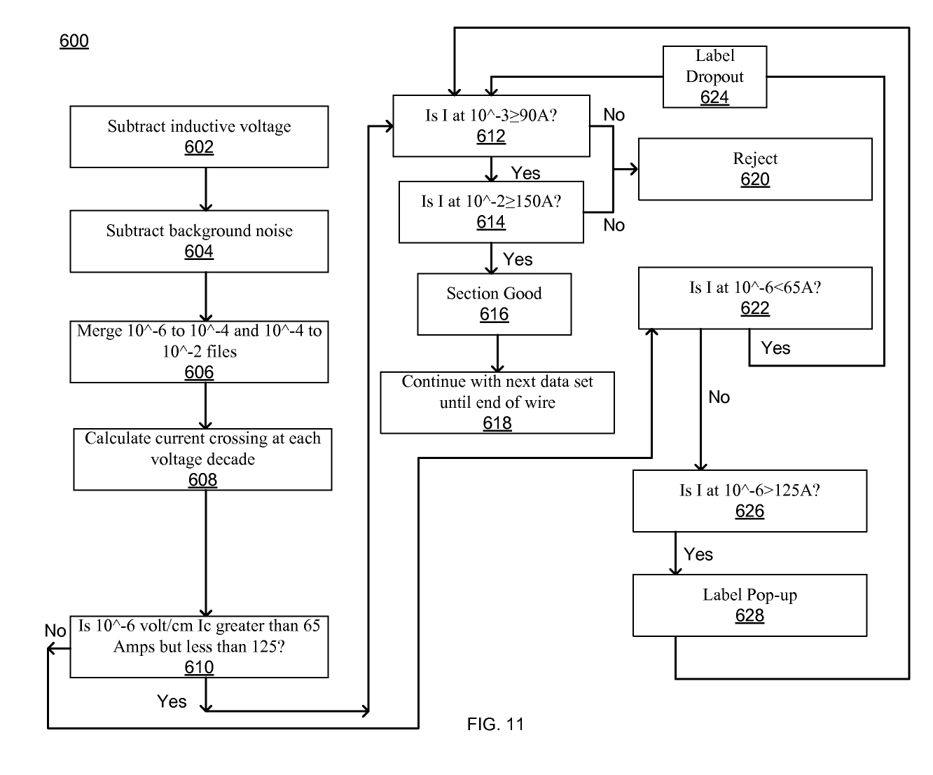

Referring now to FIG. 11, a method 600 for analyzing the data received at second testing device 406 is provided. The post processing program may be configured to subtract background voltage signals (604) from the raw VI datapoints. In some cases, the signals subtracted are those due to the inductive signal generated due to the fast ramp rate and noise (602). A signal resulting from the operational characteristics of the power supply may also be subtracted.

Once the parasitic signals are subtracted the low e-field and the mid e-field curves may be joined into one curve. It is at this point that current crossings at 10-6 (Ic), 10-5, 10-4, 10-3, 10-2 volts/cm, etc are calculated and reported (606, 608).

Method 600 may further include determining whether the Ic fits within a particular range. For the purposes of this example, the range may be between 65 and 125 A. For example, the method may include determining whether the Ic at 10̂-6 V/cm is greater than 65 A but less than 125 A (610). If so, and additionally if the Ic at 10̂-3 is ≧90 A (612) and the Ic at 10̂-2 is ≧150 A (614), the portion may be deemed acceptable (616) and the method may continue with the next data set until the end of the wire is reached (618). If the Ic at 10̂-3 is not ≧90 A and the Ic at 10̂-2 is not ≧150 A, the portion may be rejected (620). If the Ic at 10̂-6 volt/cm is less than 65 A (622) it will be labeled a dropout (624). If it is not and it is greater than 125 A, it will be labeled a pop-up (628).

Once all this data is reduced the suitability of any particular 4 cm portion of wire for use in the fault current limiting cable application may be determined (e.g., portions 408A-408E shown in FIG. 9). Additionally, the data obtained may be free of thermal affects allowing for a far more rigorous modeling of the cable thermal behavior in fault conditions.

In the past, the performance of HTS wires has been characterized almost extensively by their critical current or Ic. As discussed above, the Ic is defined as the current that flows when a 1 uV/cm electric field is applied to the HTS wire at 77.3K (i.e., boiling point of liquid nitrogen) in a self field (i.e. no external magnetic fields). For example, 1 uV applied across 1 cm of wire or 100 uV applied across 100 cm would result in a 1 uV/cm electric field. Using existing methodologies, design considerations for HTS wires only required that a minimum Ic be specified. However, for a fault-current limiter application, such as those described herein, a maximum Ic must also be specified for the fault-current limiting function to limit current within an acceptable range. To express the HTS wire's voltage versus current or V-I curve, a minimum “n-value” at Ic was specified.

Generally, in the field of superconductivity, the n-value refers to the exponent in the HTS wire equation shown below,

Ewire=0.0001*(Iwire/Ic)^{N} V/m (Equation 1)

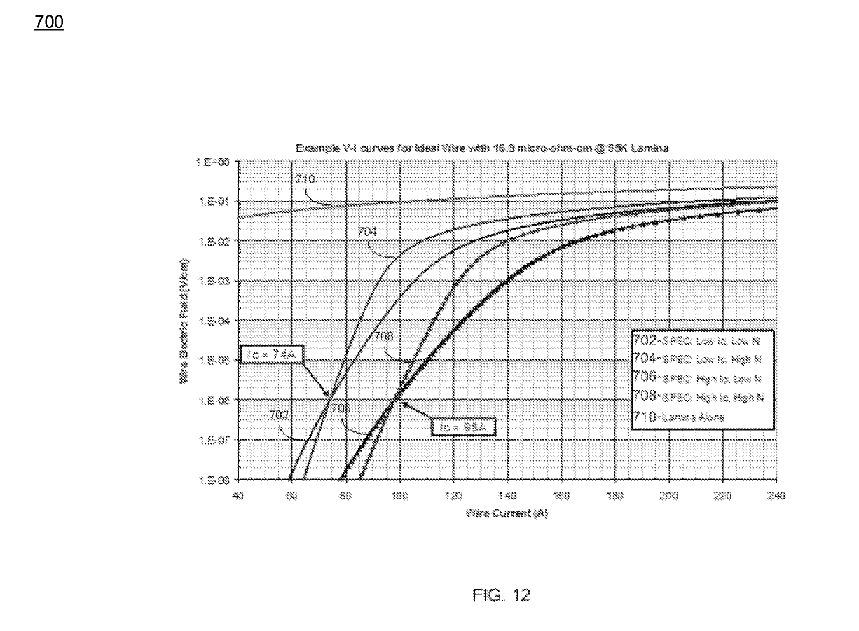

In this equation, Ic is the critical current of the wire and Iwire is the current flowing through the wire that produces the electric field Ewire. The 0.0001 in Equation 1 normalizes the standard Ic definition units of 1 uV/cm to MKS units of V/m. The V-I curves resulting from these n-values are shown in FIG. 12, which is described in further detail below. For a more detailed discussion of n-values, see n-Value and Second Derivative of the Superconductor Voltage-Current Characteristic by L. F. Goodrich, A. N. Srivastava, M. Yuyama, and H. Wada, published in IEEE Transactions on Applied Superconductivity, Vol. 3, No. 1, March 1993.

Generally, in an HTS wire, variations detected above a certain threshold are referred to as pop-ups if the Ic spikes in an upwards direction. Alternatively, variations detected below a certain threshold are referred to as drop-outs if the Ic spikes downwards.

In the past, the presence of these drop-out sections may have rendered the HTS wire defective, thus requiring the removal of a portion of the wire. The remaining “acceptable” wire was then spliced together to make a continuous wire. However, existing techniques, which require the use of n-values to identify defective portions of wire have not been successful in precisely identifying these defective portions. As a result, excessive amounts of acceptable wire are often discarded along with the defective wire.

The implementations described herein may be used to more accurately identify portions of HTS wire that would have been discarded using the existing approach, namely the Ic value and n-value based methodology. In some cases, portions of HTS wire that have a low Ic value actually behave better than portions of wire having a higher Ic value at higher E fields, which may be critical for a true understanding of how a portion of HTS wire will react during a fault current limiting application. An understanding of the behavior of HTS wire at Ec (critical electric field) alone may not be sufficient to characterize that portion of wire as acceptable or unacceptable. In other words, the portions of HTS wire having the lowest Ic values are not necessarily where the hotspots will occur when the current through the wire and E field at those portions of the wire increase significantly during a fault condition, as the Ic value and n-value based methodology would predict. This disclosure expands the analysis beyond the critical current value, by determining a plurality VI datapoints above Ec, in some cases by more than a factor of ten. It is at this test range, at electric field levels well over Ec, that the “flux-flow regime” phenomenon of some portions of HTS wire may be determined and analyzed.

Referring now to FIG. 12, a diagram 700 depicting VI curves for an ideal wire is shown. Here, the wire current in amperes is plotted along the x-axis while the wire electric field in Volts/cm is plotted along the y-axis. In this example, a modified lamina having a resistivity of 16.9 micro-ohm-cm was used.

Diagram 700 shows VI curves 702, 704, 706, 708, and 710. VI curves 702 and 704 indicate portions of HTS wire having a low Ic (e.g., 74A). In contrast, VI curves 706 and 708 indicate portions of HTS wire having a high Ic (e.g., 98A). The VI curve for the lamina alone is indicated by reference numeral 710. Further, VI curves 702 and 706 have a relatively low n-value, conversely VI curves 704 and 708 have a relatively high n-value.

It should be noted that the slope of the V-I curves appears fairly constant below an electric field of 1E-03 V/cm. In the range of 1E-03 to 1E-02 V/cm, the curves tend to exhibit a “bending over” phenomenon. This may occur when the effective HTS resistance approaches that of the metallic lamina that sandwiches the HTS insert. In FIG. 12, the V-I curve of the lamina alone is indicated by reference numeral 710, (i.e., the line passing through 1E-01 V/cm at 100 A). At higher field strengths, current in the wire may begin to split between the HTS layer and the lamina. This may explain why the V-I curves “bend over” and run approximately parallel to the lamina V-I curve.

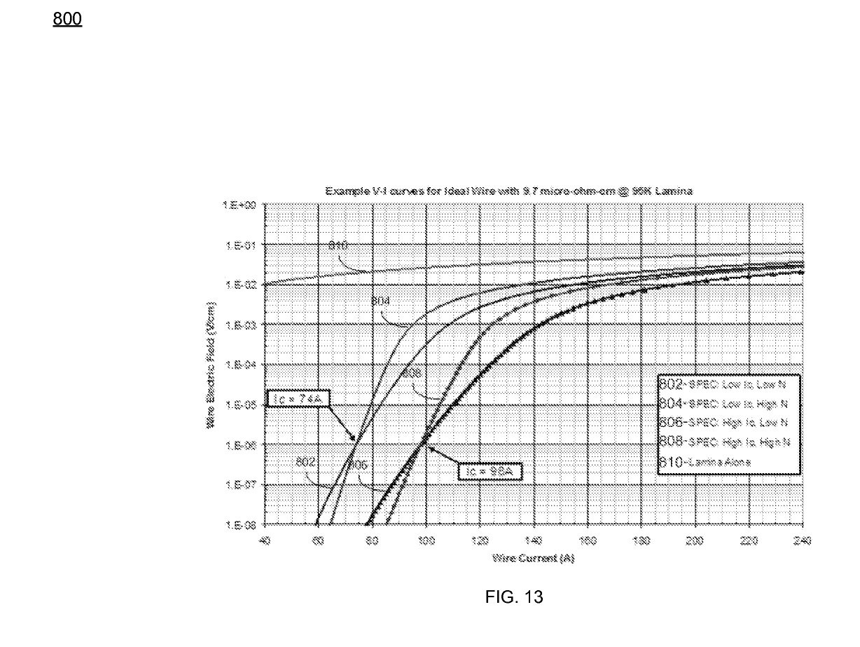

FIG. 13 shows yet another diagram 800 depicting VI curves 802, 804, 806, 808, and 810 for an ideal wire. In this example, the lamina has a lower resistivity of approximately 9.7 micro-ohm-cm, thus the HTS wire V-I curves start to “bend over” at a lower electric field.

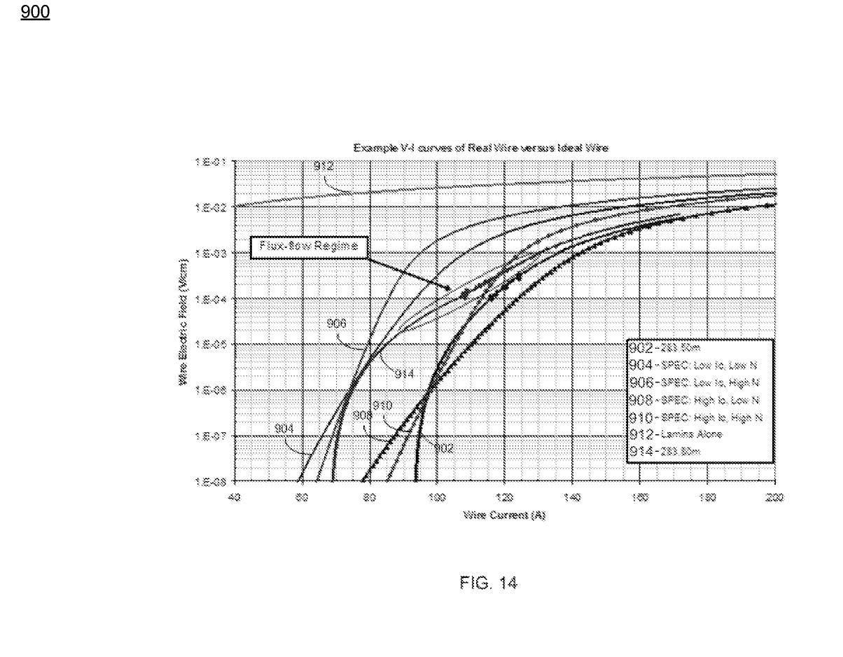

Referring now also to FIG. 14, a diagram of a composite VI curve 900 showing individual VI curves 902, 904, 906, 908, 910, 912, and 914 is provided. This diagram indicates the differences between real wire and “ideal” wire. For the purposes of this disclosure, an “ideal wire” refers to a hypothetical wire model based upon the minimum Ic and n-values. Again, the VI curves shown in FIG. 14 are plotted on a two-dimensional axis with wire current in amperes on the x-axis and wire electric field in Volts/cm on the y-axis. The VI curves corresponding to real wire may be generated by second testing device 406 and may be based upon the VI datapoints described herein.

In this example, the VI curves corresponding to the “real” wires are shown by reference numerals 902 and 914 and the VI curves corresponding to the “ideal” wires are shown by reference numerals 904, 906, 908, and 910. The VI curve for the lamina alone is depicted by reference numeral 912.

FIG. 14 illustrates how V-I curves 902, 914 corresponding to real wires near the minimum (labeled 283.80 m) and maximum (labeled 283.50 m) Ic limits compare against the ideal V-I curves predicted by the Ic and n-values of Equation 1. A key observation is that around 1E-06 V/cm where Ic is typically measured, the actual V-I curves do not have a constant n-value as predicted by Equation 1. Instead, the n-value decreases. This is especially true for the 283.80 m V-I curve 914 where it flattens to a much lower n-value in the 1E-05 to 1E-03 V/cm range. This is known as the “flux-flow regime” of HTS wire. In the flux flow regime, as current increases, the flux vortices may become unpinned and start breaking away from their fixed position and begin to flow. Therefore, Equation 1 does not appear to accurately represent the wire V-I curve at field strengths above 1E-05 V/cm. For the majority of HTS applications, where the operating current is below Ic, this is a non-issue. However, for fault-current limiting applications where wire current exceeds Ic, having a better way to model and specify the wire V-I characteristic is critical to predicting the wire heating during a fault-current limiting event.

As such, implementations described herein may be used to identify portions of HTS wire 402 that will experience a lower temperature rise during a fault current limiting situation than that expected by the critical current and n-value analysis performed in the past. Because of the ‘bending over’ effect exhibited by the VI curves shown herein, portions of superconducting wire that were once deemed defective may now be kept. The portions of the HTS wire that exhibit this effect may result in a lower voltage drop at higher currents, such as those present during FCL applications.

As discussed above, first testing device 404 may be configured to perform a VI test for each of the portions of HTS wire 402 (1102). More specifically, the VI test may include determining a plurality of VI data points for each of portions 408A-E of HTS wire 402. These VI data points may then be used to generate VI curves (1106), such as those shown in FIGS. 14-15. In some embodiments, the first VI datapoint may be at about (Ic (critical current), Ec (critical electric field)) and a second VI datapoint may be about (Ix, Ex). In some cases, Ex may be at least 10 times Ec, which is approximately 1.00 μV/cm, and Ix may be approximately equal to the current resulting at that voltage drop (1111). For example, for a given portion of HTS wire Ec is 1.00 μV/cm while Ex is at least 10 μV/cm. However, for some applications, Ex may be as high as 1 V/cm or even higher in some cases. Second testing device 406 may be configured to analyze these VI data points for each portion of superconducting wire to determine if one or more of portions of HTS wire is defective (1104).

Second testing device 406 may be configured to generate at least one VI curve from the plurality of VI data points. In some cases this may be achieved by superimposing at least a portion of the plurality of VI curves to form a composite VI curve as shown in FIGS. 14 and 15 (1114). Composite VI curve may be analyzed to determine if one or more portions of wire is defective (1112). Here, again it should be noted that the VI datapoints are determined without requiring the use of an n-value.

Referring again to FIG. 15, a diagram depicting a composite VI curve 1000 is shown. Composite VI curve 1000 may include individual VI curves 1002, 1004, 1006, 1008, and 1010, each corresponding to a respective one of the five individual portions 408A-408E of HTS wire 402 shown in FIG. 9.

Second testing device 406 may be further configured to analyze the composite VI curve 1000 to determine if one or more of portions 408A-E of HTS wire 402 is defective. In some cases, a portion of HTS wire 402 may be deemed defective if the portion is unacceptable for use in a fault current limiting circuit.

Second testing device 406 may be further configured to generate a test acceptability curve 1012 that defines a superconducting defect (1108). The test acceptability curve may be application specific and may be determined by defining the maximum acceptable E field over a range of operating currents, I, which will ensure fault current limiting behavior to the required levels while not damaging the cable due to excessive heating, which may or may not lead to damage of the insulation or other critical cable components. The acceptability curve also assures that fault currents will be limited as required by the particular application. Determining the bounds of the curve may be dependent upon multiple factors, including the level of current to be limited by the cable, cable operating current, cable length, voltage withstand, etc. Test acceptability curve 1012 may be used in the analysis of VI curves 1002, 1004, 1006, 1008, and 1010. This analysis may include comparing each of the VI curves 1002, 1004, 1006, 1008, and 1010 to test acceptability curve 1012 to identify a defective portion of HTS wire 402 (1116). In this example, none of the five VI curves shown in FIG. 15 cross acceptability curve 1012 and are therefore non-defective. If a defective portion is identified that portion may be removed and/or replaced with a splice (1110) as is described below.

A defect-free superconducting wire may be obtained in accordance with the methods described herein. The term “defect free” as used herein may refer to a portion of HTS wire that is suitable for a particular application, such as, in a fault-limiting application. For example, a portion of HTS wire 402 that is bounded by acceptability curve 1012 may be deemed “defect free.” The defect-free superconducting wire may be produced by performing a voltage/current (VI) test for each of a plurality of portions 408 of HTS wire 402. The VI test may include determining a plurality of VI data points for each of the plurality of portions 408 of HTS wire 402. In some cases, the VI datapoints may include a first VI datapoint of about Ic (critical current), Ec (critical electric field) and a second VI datapoint of about (Ix, Ex). Here, as above, Ec is approximately 1.00 μV/cm, Ex may be at least 10 times Ec, and Ix may be approximately equal to the current resulting at that voltage drop. If one or more portions 408 of the HTS wire 402 is defective, that portion may be removed resulting in a defect-free HTS wire.

Additionally, a high temperature superconducting wire may be obtained using the methods described herein. HTS wire may have a plurality of portions along its length and wherein at least one of said portions has a decreasing voltage to current ratio when a voltage/current (VI) test is performed for said portion of the superconducting wire, said decreasing voltage to current ratio decreasing at a rate greater than an N-value test would indicate. Referring again to FIG. 14, VI curves 902 and 914 show two portions of HTS wire that have a V/I ratio decreasing at a rate faster than an n-value test would indicate. The VI test may include determining a plurality of VI data points at a first VI datapoint of about (Ic (critical current), Ec (critical electric field)) and at a second VI datapoint of about (Ix, Ex), wherein Ex is at least 10 times Ec and Ix is approximately equal to the current resulting at that voltage drop.

In another implementation, a high temperature superconducting integrated fault current limiting cable may be obtained using the methods described herein. HTS integrated FCL cable may include a plurality of high temperature superconducting wires. The wires may include a plurality of portions along their lengths and wherein at least one of said wires has a wire portion with a decreasing voltage to current ratio when a voltage/current (VI) test is performed for said portion of the superconducting wire, said decreasing voltage to current ratio decreasing at a rate greater than an n-value test would indicate. The VI test may include determining a plurality of VI data points at a first VI datapoint of about (Ic (critical current), Ec (critical electric field)) and at a second VI datapoint of about (Ix, Ex), wherein Ex is at least 10 times Ec and Ix is approximately equal to the current resulting at that voltage drop.

Accordingly the present disclosure is directed to a system and method for analyzing superconducting wire. Implementations described herein may be used to identify portions of superconducting wire that will experience a lower temperature rise during a FCL situation than that expected by an Ic and n-value analysis. Because of the ‘bending over’ effect of the VI curves shown herein, portions of superconducting wire that were once deemed defective may now be kept. The portions of the HTS wire that exhibit this effect result in a lower voltage drop at higher currents, such as those present during FCL applications.

A number of implementations have been described. Nevertheless, it will be understood that various modifications may be made. Accordingly, other implementations are within the scope of the following claims.

What is claimed is:

1. A test method for analyzing a superconducting wire comprising:
performing a voltage/current (VI) test for each of a plurality of portions of said superconducting wire, wherein the VI test includes determining a plurality of VI data points for each of the plurality of portions of said superconducting wire, said plurality of VI data points including a first VI datapoint at about (Ic (critical current), Ec (critical electric field)) and a second VI datapoint at about (Ix, Ex), wherein Ex is at least 10 times Ec and Ix is approximately equal to the current resulting at that voltage drop; and
analyzing said plurality of VI data points for each said portion of superconducting wire to determine if one or more of said portions of superconducting wire is defective.

2. The test method of claim 1 further comprising:
generating at least one VI curve from said plurality of VI data points, said generating including superimposing at least a portion of the plurality of VI curves to form a composite VI curve;
wherein analyzing said plurality of VI data points includes analyzing the composite VI curve to determine if one or more of said plurality of portions of superconducting wire is defective.

3. The test method of claim 1 wherein a portion of superconducting wire is deemed defective if the portion of superconducting wire is unacceptable for use in a fault current limiting circuit.

4. The test method of claim 1 further comprising:
generating a test acceptability curve that defines a superconducting defect.

5. The test method of claim 4 wherein analyzing at least a portion of each of said plurality of VI curves includes:
comparing each of said plurality of VI curves to said test acceptability curve to identify at least one defective portion of said plurality of portions of superconducting wire.

6. The test method of claim 5 further comprising:
if at least one defective portion of said plurality of portions of superconducting wire is identified, replacing said at least one defective portion with a splice.

7. The test method of claim 1 wherein Ec is approximately 1.00 μV/cm.

8. The test method of claim 7 wherein determining said plurality of VI datapoints does not require the calculation of an n-value.

9. A testing system configured to analyze a superconducting wire comprising:
a first testing device configured to perform a voltage/current (VI) test for each of a plurality of portions of said superconducting wire, wherein the VI test includes determining a plurality of VI data points for each of the plurality of portions of said superconducting wire, said plurality of VI data points including a first VI datapoint at about (Ic (critical current), Ec (critical electric field)) and a second VI datapoint at about (Ix, Ex), wherein Ex is at least 10 times Ec and Ix is approximately equal to the current resulting at that voltage drop; and
a second testing device configured to analyze said plurality of VI data points for each said portion of superconducting wire to determine if one or more of said portions of superconducting wire is defective.

10. The testing system of claim 9 wherein said second testing device is further configured to
generate at least one VI curve from said plurality of VI data points by superimposing at least a portion of the plurality of VI curves to form a composite VI curve, said second testing device further configured to analyze the composite VI curve to determine if one or more of said plurality of portions of superconducting wire is defective.

11. The testing system of claim 9 wherein a portion of superconducting wire is deemed defective if the portion of superconducting wire is unacceptable for use in a fault current limiting circuit.

12. The testing system of claim 9 wherein said second testing device is further configured to generate a test acceptability curve that defines a superconducting defect.

13. The testing system of claim 12 wherein analyzing at least a portion of each of said plurality of VI curves includes:
comparing each of said plurality of VI curves to said test acceptability curve to identify at least one defective portion of said plurality of portions of superconducting wire.

14. The testing system of claim 9 wherein Ec is approximately 1.00 μV/cm.

15. The testing system of claim 14 wherein said plurality of VI datapoints are determined without the calculation of an n-value.

16. A defect-free superconducting wire obtained by a process comprising:
performing a voltage/current (VI) test for each of a plurality of portions of said superconducting wire, wherein the VI test includes determining a plurality of VI data points for each of the plurality of portions of said superconducting wire, said plurality of VI data points including a first VI datapoint at about Ic (critical current), Ec (critical electric field) and a second VI datapoint at about (Ix, Ex), wherein Ex is at least 10 times Ec and Ix is approximately equal to the current resulting at that voltage drop;
analyzing said plurality of VI data points for each said portion of superconducting wire to determine if one or more of said portions of superconducting wire is defective; and
removing a defective portion, if present.

17. The defect-free superconducting wire of claim 16, the process further comprising:
generating at least one VI curve from said plurality of VI data points, said generating including superimposing at least a portion of the plurality of VI curves to form a composite VI curve;
wherein analyzing said plurality of VI data points includes analyzing the composite VI curve to determine if one or more of said plurality of portions of superconducting wire is defective.

18. The defect-free superconducting wire of claim 16 wherein a portion of superconducting wire is deemed defective if the portion of superconducting wire is unacceptable for use in a fault current limiting circuit.

19. The defect-free superconducting wire of claim 16, the process further comprising:
generating a test acceptability curve that defines a defective portion of superconducting wire.

20. The defect-free superconducting wire of claim 19 wherein analyzing at least a portion of each of said plurality of VI curves includes:
comparing each of said plurality of VI curves to said test acceptability curve to identify at least one defective portion of said plurality of portions of superconducting wire.

21. A high temperature superconducting wire, wherein said wire has a plurality of portions along its length and wherein at least one of said portions has a decreasing voltage to current ratio when a voltage/current (VI) test is performed for said portion of the superconducting wire, said decreasing voltage to current ratio decreasing at a rate greater than an n-value test would indicate; the VI test includes determining a plurality of VI data points, said plurality of VI data points including a first VI datapoint at about (Ic (critical current), Ec (critical electric field)) and a second VI datapoint at about (Ix, Ex), wherein Ex is at least 10 times Ec and Ix is approximately equal to the current resulting at that voltage drop.

22. A high temperature superconducting integrated fault current limiting cable comprising:
a plurality of high temperature superconducting wires; wherein said wires have a plurality of portions along their lengths and wherein at least one of said wires has a wire portion with a decreasing voltage to current ratio when a voltage/current (VI) test is performed for said portion of the superconducting wire, said decreasing voltage to current ratio decreasing at a rate greater than an n-value test would indicate; the VI test includes determining a plurality of VI data points, said plurality of VI data points including a first VI datapoint at about (Ic (critical current), Ec (critical electric field)) and a second VI datapoint at about (Ix, Ex), wherein Ex is at least 10 times Ec and Ix is approximately equal to the current resulting at that voltage drop.
